(19) United States
(12) Patent Application Publication
(10) Pub. No.: US 2026/0101754 A1
(43) Pub. Date: Apr. 9, 2026

(54) SEMICONDUCTOR PACKAGE

(71) Applicant: Samsung Electronics Co., Ltd., Suwon-si (KR)

(72) Inventors: Eun Beom JEON, Suwon-si (KR); Gi Hun LEE, Suwon-si (KR)

(21) Appl. No.: 19/051,739

(22) Filed: Feb. 12, 2025

(30) Foreign Application Priority Data
Oct. 7, 2024 (KR) 10-2024-0135583

(51) Int. Cl. H01L 23/00; H01L 23/538

(52) U.S. Cl. CPC H10W 42/121; H10W 70/611; H10W 70/65; H10W 72/884; H10W 90/734; H10W 90/754

(57) ABSTRACT

A semiconductor package is provided. The semiconductor package comprises a substrate, a semiconductor chip which is disposed on the substrate, and includes a plurality of edges, and a metal pad which is disposed inside the substrate, and directly abuts against at least one edge of the plurality of edges, wherein the metal pad is electrically isolated.

### CROSS-REFERENCE TO RELATED APPLICATION

This application claims priority under 35 U.S. C. § 119 from Korean Patent Application No. 10-2024-0135583, filed on Oct. 7, 2024, in the Korean Intellectual Property Office, and all the benefits accruing therefrom under 35 U.S. C. § 119, the contents of which in its entirety are herein incorporated by reference.

### BACKGROUND

### 1. Field of the Disclosure

The present disclosure relates to a semiconductor package.

### 2. Description of the Related Art

A semiconductor substrate may be damaged or deformed by a pressure applied from a semiconductor device mounted on the semiconductor substrate. This is also true when a plurality of semiconductor devices are mounted on the semiconductor substrate.

For example, the plurality of semiconductor devices may be mounted on one semiconductor substrate, using a flip chip bonding technique and/or a wire bonding technique. When the plurality of semiconductor devices are mounted on one semiconductor substrate, the semiconductor substrate may be damaged or deformed by the pressure applied from the plurality of semiconductor devices.

### SUMMARY

Aspects of the present disclosure provide a semiconductor package that may effectively prevent deformation due to external factors.

According to an aspect of the present disclosure, there is provided a semiconductor package comprising a substrate, a semiconductor chip which is disposed on the substrate, and includes a plurality of edges, and a metal pad which is disposed inside the substrate, and directly abuts against at least one edge of the plurality of edges, wherein the metal pad is electrically isolated.

According to an aspect of the present disclosure, there is provided a semiconductor package comprising a first semiconductor chip and a second semiconductor chip which are mounted on a substrate to be spaced apart from each other, a first metal pad which is disposed in the substrate and comes into contact with an edge of the first semiconductor chip, and a second metal pad which is disposed in the substrate and comes into contact with an edge of the second semiconductor chip, wherein each of the first metal pad and the second metal pad is electrically isolated.

According to an aspect of the present disclosure, there is provided a semiconductor package comprising a substrate, a plurality of substrate pads which are disposed on an upper face of the substrate, a first semiconductor chip which is disposed on the substrate and includes a plurality of edges, a plurality of chip pads which are disposed on an upper face of the first semiconductor chip, a plurality of wires which connect the plurality of substrate pads and the plurality of chip pads one-to-one, a metal pad which is disposed in the substrate and directly abuts against at least one edge of the plurality of edges, and a plurality of second semiconductor chips which are stacked on the first semiconductor chip in a cascade type.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is an example layout diagram for explaining a semiconductor package according to example embodiments;

FIG. 2 is a cross-sectional view taken along A-A′ of FIG. 1;

FIG. 3 is an enlarged view of a region Q of FIG. 2;

FIG. 4 is an enlarged view of a region Q of FIG. 2 to explain a semiconductor package according to example embodiments;

FIG. 5 is an enlarged view of a region Q of FIG. 2 to explain a semiconductor package according to example embodiments;

FIG. 6 is a cross-sectional view taken along A-A′ of FIG. 1 to explain a semiconductor package according to example embodiments;

FIG. 7 is an enlarged view of a region R of FIG. 6 to explain a semiconductor package according to example embodiments;

FIG. 8 is a cross-sectional view taken along A-A′ of FIG. 1 to explain a semiconductor package according to example embodiments;

FIG. 9 is an enlarged view of a region S of FIG. 8 to explain the semiconductor package according to example embodiments;

FIG. 10 is an example layout diagram for explaining a semiconductor package according to example embodiments;

FIG. 11 is a cross-sectional view taken along A-A′ of FIG. 10 to explain the semiconductor package according to example embodiments;

FIG. 12 is an example layout diagram for explaining a semiconductor package according to example embodiments;

FIG. 13 is an example layout diagram for explaining a semiconductor package according to example embodiments;

FIG. 14 is an example layout diagram for explaining a semiconductor package according to example embodiments;

FIG. 15 is an example layout diagram for explaining a semiconductor package according to example embodiments;

FIG. 16 is a cross-sectional view taken along B-B′ of FIG. 15 to explain the semiconductor package according to another example embodiment;

FIG. 17 is an enlarged view of a region T of FIG. 16 to explain the semiconductor package according to another example embodiment;

FIG. 18 is a cross-sectional view for explaining the semiconductor packages according to some other example embodiments;

FIG. 19 is a cross-sectional view for explaining a semiconductor package according to some other example embodiments; and

FIG. 20 is a cross-sectional view for explaining a semiconductor package according to some other example embodiments.

### DETAILED DESCRIPTION OF THE EMBODIMENTS

Hereinafter, example embodiments will be described with reference to the accompanying drawings. Like reference characters refer to like elements throughout.

Although terms such as first and second are used to explain various elements or components in the present specification, it goes without saying that these elements or components are not limited by these terms. These terms are only used to distinguish a single element or component from other elements or components. Therefore, it goes without saying that a first element or component referred to below may be a second element or component within the technical idea of the present disclosure.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

The term “buried” may refer to structures, patterns, and/or layers that are formed at least partially below a top surface of another structure, pattern, and/or layer. In some embodiments, when a first structure, pattern, and/or layer is “buried” in a second structure, pattern, and/or layer, the second structure, pattern, and/or layer may surround at least a portion of the first structure, pattern, and/or layer. For example, a first structure, pattern, and/or layer first may be considered to be buried when it is at least partially embedded in a second structure, pattern, and/or layer.

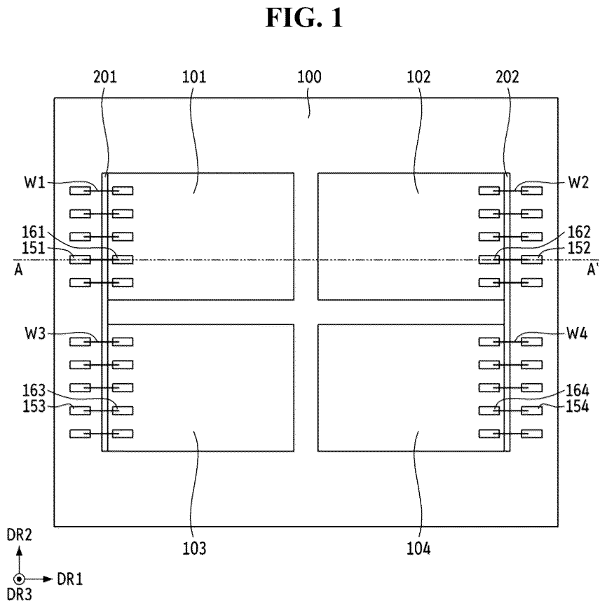

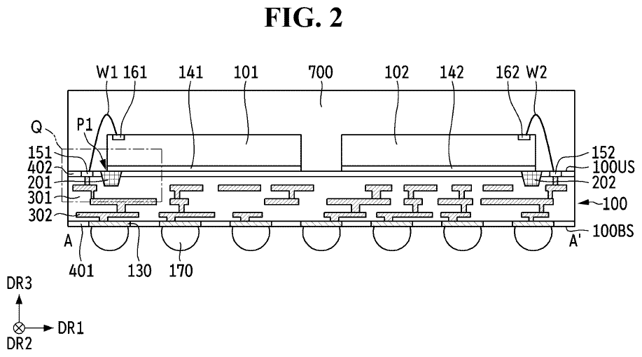

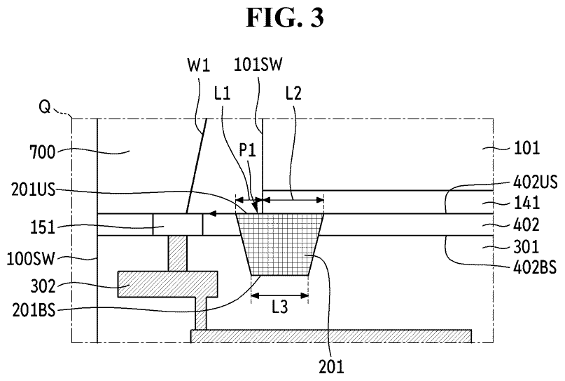

FIG. 1 is an example layout diagram for explaining a semiconductor package according to some example embodiments. FIG. 2 is a cross-sectional view taken along A-A′ of FIG. 1. FIG. 3 is an enlarged view of a region Q of FIG. 2. For reference, FIG. 1 is a cross-sectional view in which an encapsulant 700 is omitted for convenience of explanation.

Referring to FIGS. 1 to 3, the semiconductor package according to some embodiments of the present disclosure may include a package substrate 100, first to fourth semiconductor chips 101, 102, 103, and 104, and the encapsulant 700.

The package substrate 100 may include an insulating layer 301, a metal wiring layer 302, substrate connection terminals 170, lower substrate pads 130, a first passivation film 401, a second passivation film 402, a plurality of substrate pads 151, 152, 153, and 154, a first metal pad 201, and a second metal pad 202.

The package substrate 100 may be a wiring structure for a package. For example, the package substrate 100 may be a printed circuit wiring structure (PCB: printed circuit board) or a ceramic wiring structure. Alternatively, it goes without saying that the package substrate 100 may be a wiring structure for a wafer level package (WLP) manufactured at a wafer level. The package substrate 100 may include a lower face 100BS and an upper face 100US that are opposite to each other.

The package substrate 100 may extend in a first direction DR1 and a second direction DR2. The first direction DR1 and the second direction DR2 may each mean a direction parallel to the upper face 100US of the package substrate. A third direction DR3 may mean a direction that intersects each of the first direction DR1 and the second direction DR2, and is perpendicular to the upper face 100US of the package substrate.

The package substrate 100 may be, for example, a printed circuit board (PCB) or a ceramic substrate. However, the technical idea of the present disclosure is not limited thereto.

When the package substrate 100 is the printed circuit board, the insulating layer 301 may include or be formed of at least one material selected from phenol resin, epoxy resin, and polyimide. The insulating layer 301 may include, for example, at least one material selected from FR-4, tetrafunctional epoxy, polyphenylene ether, epoxy/polyphenylene oxide, BT (bismaleimide triazine), thermount, cyanate ester, polyimide, and liquid crystal polymer. A surface of the package substrate 100 may be covered with solder resist. For example, a first passivation film 401 and a second passivation film 402 formed on the surface of the package substrate 100 may be solder resist. In example embodiments, the first passivation film 401 may be formed on a bottom surface of the package substrate 100, and the second passivation film 402 may be formed on an upper surface of the package substrate 100. However, the technical idea of the present disclosure is not limited thereto.

Although the package substrate 100 is shown as being a single layer, this is only for convenience of explanation. For example, the package substrate 100 may be made up of multi-layers to form a multi-layer metal wiring layer 302.

Although the insulating layer 301 is shown as being a single layer, this is only for convenience of explanation. For example, it is a matter of course that the insulating layer 301 is made up of multi-layers, and multi-layer wiring patterns may be formed therein.

The metal wiring layer 302 may be formed inside the insulating layer 301. An electrical signal may move through the metal wiring layer 302. In other words, the metal wiring layer 302 may be used to electrically connect the package substrate 100 with other components. The metal wiring layer 302 may electrically connect the substrate connection terminals 170 and the plurality of substrate pads 151, 152, 153, and 154. The substrate connection terminals 170 and the plurality of substrate pads 151, 152, 153, and 154 may include a conductive material. For example, the substrate connection terminals 170, the metal wiring layer 302, and the substrate pads 151, 152, 153, and 154 may be formed of or include gold (Au), silver (Ag), copper (Cu), nickel (Ni), or aluminum (Al).

In some embodiments, the substrate connection terminals 170 may be formed on the lower face 100BS of the package substrate 100. The substrate connection terminals 170 may be attached to the substrate connection terminals 170. The substrate connection terminals 170 may come into contact with the lower substrate pads 130. The substrate connection terminals 170 may be disposed below the lower substrate pads 130. The substrate connection terminals 170 may include solder balls or solder bumps. The substrate connection terminals 170 may have, for example, but not limited to, a spherical shape or an elliptical shape. Of course, the number, interval, placement, shape, and the like of the substrate connection terminals 170 are not limited to those shown in the drawings and may vary depending on the design. The substrate connection terminals 170 may be formed of or include, but not limited to, tin (Sn), indium (In), bismuth (Bi), antimony (Sb), copper (Cu), silver (Ag), zinc (Zn), lead (Pb) or a combination thereof. The lower substrate pads 130 may be formed of or include gold (Au), silver (Ag), copper (Cu), nickel (Ni), or aluminum (Al).

The substrate connection terminals 170 may electrically connect the metal wiring layer 302 to an external device. For example, the metal wiring layer 302 may contact the lower substrate pads 130, and may provide an electrical signal to the substrate connection terminals 170 through the lower substrate pads 130. Accordingly, the substrate connection terminals 170 may provide an electrical signal to the metal wiring layer 302, or provide an electrical signal provided from the metal wiring layer 302 to an external device.

A second passivation film 402, a plurality of substrate pads 151, 152, 153 and 154, a first metal pad 201, and a second metal pad 202 may be disposed on the upper face 100US of the package substrate 100.

The plurality of substrate pads 151, 152, 153 and 154 may be used to electrically connect the package substrate 100 to other components. For example, first substrate pads 151 may electrically connect the package substrate 100 and the first semiconductor chip 101, second substrate pads 152 may electrically connect the package substrate 100 and the second semiconductor chip 102, third substrate pads 153 may electrically connect the package substrate 100 and the third semiconductor chip 103, and fourth substrate pads 154 may electrically connect the package substrate 100 and the fourth semiconductor chip 104. The plurality of substrate pads 151, 152, 153, and 154 may include, for example, but not limited to, metal materials such as copper (Cu) or aluminum (Al).

For reference, FIG. 1 shows only four semiconductor chips 101, 102, 103, and 104, but the present disclosure is not limited thereto. As another example, one semiconductor chip may be disposed on the package substrate 100, or four or more plurality of semiconductor chips may be disposed.

The first to fourth semiconductor chips 101, 102, 103, and 104 may be logic semiconductor chips. The logic semiconductor chips may be, for example, but not limited to, an application processor (AP) such as a central processing unit (CPU), a graphic processing unit (GPU), a field-programmable gate array (FPGA), a digital signal processor, an encryption processor, a micro processor, a micro controller, and an application-specific integrated circuit (ASIC).

As another example, the first to fourth semiconductor chips 101, 102, 103, and 104 may be memory semiconductor chips. The memory semiconductor chips may be, for example, volatile memories, such as a dynamic random access memory (DRAM) or a static random access memory (SRAM). Alternatively, the memory semiconductor chips included in the first to fourth semiconductor chips 101, 102, 103, and 104 may be non-volatile memories such as a flash memory, a phase-change random access memory (PRAM), a magnetic random access memory (MRAM), a ferroelectric random access memory (FeRAM) or resistive random access memory (RRAM).

For convenience of explanation, although only the structures of the first semiconductor chip 101 and the second semiconductor chip 102 will be explained below, the structures of the third semiconductor chip 103 and the fourth semiconductor chip 104 are substantially the same as the structures of the first semiconductor chip 101 and the second semiconductor chip 102.

The first semiconductor chip 101 and the second semiconductor chip 102 may include a first adhesive layer 141 and a second adhesive layer 142, respectively. The first adhesive layer 141 and the second adhesive layer 142 may be disposed on the lower faces of the first semiconductor chip 101 and the second semiconductor chip 102, respectively. The first adhesive layer 141 and the second adhesive layer 142 may cover the lower faces of the first semiconductor chip 101 and the second semiconductor chip 102, respectively. The first adhesive layer 141 may be disposed between the first semiconductor chip 101 and the package substrate 100, and the second adhesive layer 142 may be disposed between the second semiconductor chip 102 and the package substrate 100. The first adhesive layer 141 and the second adhesive layer 142 may include a non-conductive film (NCF), a non-conductive paste (NCP), an insulating polymer or an epoxy resin. However, the technical idea of the present disclosure is not limited thereto.

A first chip pad 161 and a second chip pad 162 may be disposed on the upper faces of the first semiconductor chip 101 and the second semiconductor chip 102, respectively. For example, a plurality of first chip pads 161 may be disposed on the upper face of the first semiconductor chip 101, and a plurality of second chip pads 162 may be disposed on the upper face of the second semiconductor chip 102.

The first chip pads 161 may be used to electrically connect the first semiconductor chip 101 to other components. The second chip pads 162 may be used to electrically connect the second semiconductor chip 102 to other components. The first chip pads 161 and the second chip pads 162 may be formed of or include a conductive material. For example, the first chip pad 161 may include gold (Au), silver (Ag), copper (Cu), nickel (Ni), or aluminum (Al).

The first semiconductor chip 101 may be electrically connected to the package substrate 100 through the first wires W1. For example, the first semiconductor chip 101 may be electrically connected to the package substrate 100 by the first chip pads 161, the first wires W1, and the first substrate pads 151. Although five first chip pads 161 five first substrate pads 151, and five first wires W1 are each shown, it is needless to say that the present disclosure is not limited thereto. As another example, six or more first chip pads 161, six or more first substrate pads 151, and six or more first wires W1 may be disposed.

The second semiconductor chip 102 may be electrically connected to the package substrate 100 through the second wires W2. For example, the second semiconductor chip 102 may be electrically connected to the package substrate 100 by the second chip pads 162, the second wires W2, and the second substrate pads 152. Although five second chip pads 162, five second substrate pads 152, and five second wires W2 are each shown, it is needless to say that the present disclosure is not limited thereto. As another example, six or more second chip pads 162, six or more second substrate pads 152, and six or more second wires W2 may be disposed.

The first metal pad 201 and the second metal pad 202 may be disposed inside the package substrate 100. For example, each of the first metal pad 201 and the second metal pad 202 may be buried in the package substrate 100. The first metal pad 201 may be disposed to abut against the first semiconductor chip 101 and the third semiconductor chip 103. For example, the first metal pad 201 may vertically overlap the first semiconductor chip 101 and the third semiconductor chip 103, and may contact a lower surface of the first adhesive layer 141 and a lower surface of an adhesive layer below the third semiconductor chip 103. The second metal pad 202 may be disposed to abut against the second semiconductor chip 102 and the fourth semiconductor chip 104. For example, the second metal pad 202 may vertically overlap the second semiconductor chip 102 and the fourth semiconductor chip 104, and may contact a lower surface of the second adhesive layer 142 and a lower surface of an adhesive layer below the fourth semiconductor chip 104. The first metal pad 201 may also be disposed in the space between the first semiconductor chip 101 and the third semiconductor chip 103. For example, the first metal pad 201 may extend continuously from a region below the first semiconductor chip 101 to a region below the third semiconductor chip 103. The second metal pad 202 may also be disposed in the space between the second semiconductor chip 102 and the fourth semiconductor chip 104. For example, the second metal pad 202 may extend continuously from a region below the second semiconductor chip 102 to a region below the fourth semiconductor chip 104. The first metal pad 201 may prevent the package substrate 100 from being damaged or deformed, even with the pressure applied by disposing the first semiconductor chip 101 and/or the third semiconductor chip 103 on the package substrate 100, and the second metal pad 202 may prevent the package substrate 100 from being damaged or deformed, even with the pressure applied by disposing the second semiconductor chip 102 and/or the fourth semiconductor chip 104 on the package substrate 100.

The first metal pad 201 and the second metal pad 202 may be formed of or include a metal material. For example, the first metal pad 201 and the second metal pad 202 may be formed of or include copper (Cu), but embodiments are not limited thereto. The first metal pad 201 and the second metal pad 202 may not come into contact with the metal wiring layer 302 inside the package substrate 100. In other words, an electrical signal may not be transmitted through the first metal pad 201 and the second metal pad 202. In example embodiments, the first metal pad 201 and the second metal pad 202 may be electrically isolated. Hereinafter, only the structures of the first metal pad 201, the first semiconductor chip 101, and the package substrate 100 will be described for convenience of explanation.

A point P1 at which a side wall 101SW of the first semiconductor chip 101 abuts against the package substrate 100 may be covered by the first metal pad 201. For reference, the side wall 101SW of the first semiconductor chip 101 may refer to an edge of the first semiconductor chip 101.

The first metal pad 201 may come into direct contact with the side wall 101SW of the first semiconductor chip 101. The first metal pad 201 may penetrate the second passivation film 402. The first metal pad 201 may penetrate the second passivation film 402 to come into contact with the insulating layer 301 inside the package substrate 100. In other words, the lower face 201BS of the first metal pad 201 may be disposed below the lower face 402BS of the second passivation film 402. The upper face 201US of the first metal pad 201 may be formed on the same plane as the upper face 402US of the second passivation film 402.

The first metal pad 201 abuts against a point P1 at which the side wall 101SW of the first semiconductor chip 101 abuts against the package substrate 100. The first metal pad 201 may prevent the package substrate 100 from being deformed, even with a pressure applied by disposing the first semiconductor chip 101 on the package substrate 100.

The first metal pad 201 may have a first length L1 in a direction toward the side wall 100SW of the package substrate 100, on the basis of the point P1 at which the side wall 101SW of the first semiconductor chip 101 abuts against the package substrate 100. The first metal pad 201 may have a second length L2 in a direction opposite to the direction toward the side wall 100SW of the package substrate 100, on the basis of the point P1 at which the side wall 101SW of the first semiconductor chip 101 abuts against the package substrate 100. The first semiconductor chip 101 may vertically overlap the upper face 201US of the first metal pad 201 by the second length L2. The first length L1 may be shorter than the second length L2.

For example, the sum of the first length L1 and the second length L2 may be 5 μm (micrometers) or more and 100 μor less. In other words, the length of the upper face 201US of the first metal pad 201 may be 5 μm (micrometers) or more and 100μ or less.

The length of the upper face 201US of the first metal pad 201 may be a combined length of the first length L1 and the second length L2. The length of the upper face 201US of the first metal pad 201 may be greater than the length L3 of the lower face 201BS of the first metal pad 201. In other words, the width of the first metal pad 201 in the first direction DR1 may decrease from the upper face 201US to the lower face 201BS of the first metal pad 201. For example, as shown, the first metal pad 201 may include a trapezoid shape in which the Length L3 of the lower face 201BS is shorter than the length of the upper face 201US.

The encapsulant 700 may cover both the upper face of the package substrate 100 and the upper faces of the plurality of semiconductor chips 101, 102, 103, and 104. The encapsulant may contact a portion of the upper face 201US of the first metal pad 201 that is not vertically overlapped by the first semiconductor chip 101. The encapsulant 700 may be formed of or include, for example, but not limited to, an insulating polymer material such as an epoxy molding compound (EMC).

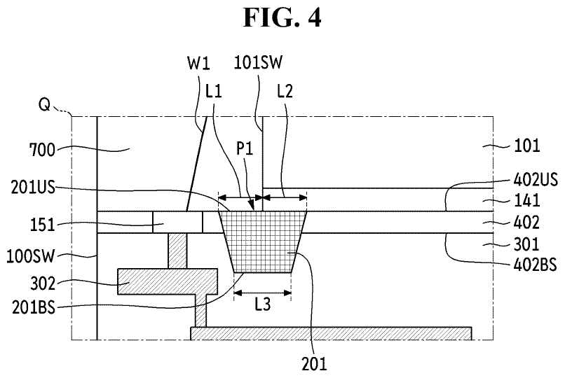

FIG. 4 is an enlarged view of a region Q of FIG. 2 to explain a semiconductor package according to some other example embodiments. For convenience of explanation, FIG. 4 will mainly explain differences from those explained in FIGS. 1 to 3. For convenience of explanation, only the first metal pad 201 will be explained.

Referring to FIG. 4, in the semiconductor package according to some other embodiments of the present disclosure, the first metal pad 201 may have a first length L1 in a direction toward the side wall 100SW of the package substrate 100, on the basis of the point P1 at which the side wall 101SW of the first semiconductor chip 101 abuts against the package substrate 100. The first metal pad 201 may have a second length L2 in a direction opposite to the direction toward the side wall 100SW of the package substrate 100, on the basis of the point P1 at which the side wall 101SW of the first semiconductor chip 101 abuts against the package substrate 100. The first semiconductor chip 101 may vertically overlap the upper face 201US of the first metal pad 201 by the second length L2. The first length L1 may be equal to the second length L2. In other words, the center of the upper face 201US of the first metal pad 201 may abut against the side wall 101SW of the first semiconductor chip 101.

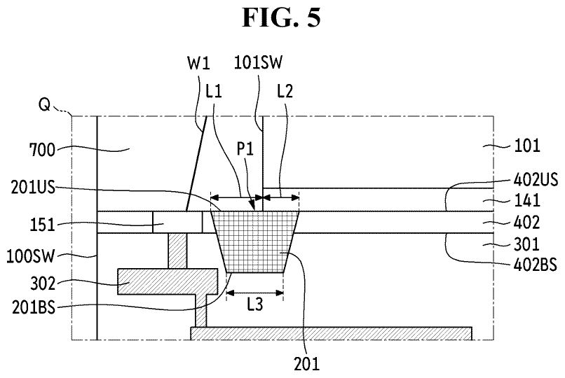

FIG. 5 is an enlarged view of a region Q of FIG. 2 to explain a semiconductor package according to some other example embodiments. For convenience of explanation, FIG. 5 will mainly explain differences from those explained in FIGS. 1 to 3. For convenience of explanation, only the first metal pad 201 will be explained.

Referring to FIG. 5, in the semiconductor package according to some other embodiments of the present disclosure, the first metal pad 201 may have a first length L1 in a direction toward the side wall 100SW of the package substrate 100, on the basis of the point P1 at which the side wall 101SW of the first semiconductor chip 101 abuts against the package substrate 100. The first metal pad 201 may have a second length L2 in the direction opposite to the direction toward the side wall 100SW of the package substrate 100, on the basis of the point P1 at which the side wall 101SW of the first semiconductor chip 101 abuts against the package substrate 100. The first semiconductor chip 101 may vertically overlap the upper face 201US of the first metal pad 201 by the second length L2. The first length L1 may be greater than the second length L2.

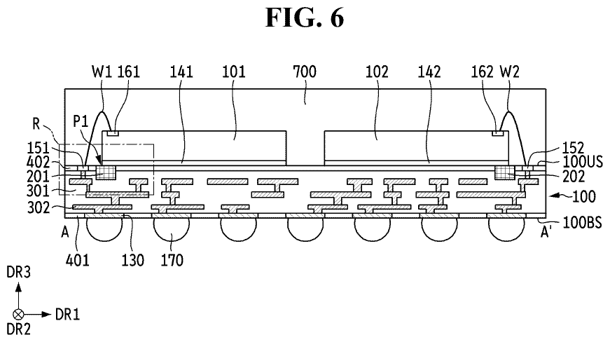

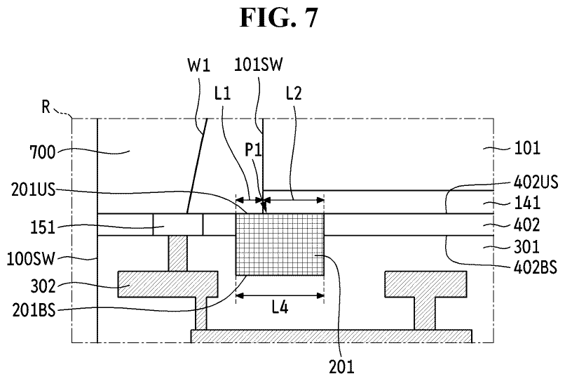

FIG. 6 is a cross-sectional view taken along A-A′ of FIG. 1 to explain a semiconductor package according to some other example embodiments. FIG. 7 is an enlarged view of a region R of FIG. 6 to explain a semiconductor package according to some other example embodiments. For convenience of explanation, in FIGS. 6 and 7, differences from those explained in FIGS. 1 to 3 will be mainly explained, and duplicate descriptions will not be repeated. For convenience of explanation, only the first metal pad 201 will be explained.

Referring to FIGS. 6 and 7, in the semiconductor package according to some other embodiments of the present disclosure, the length of the upper face 201US of the first metal pad 201 may be a combined length of the first length L1 and the second length L2. The length of the upper face 201US of the first metal pad 201 may be equal to the length L4 of the lower face 201BS of the first metal pad 201. In other words, the width of the first metal pad 201 in the first direction DR1 may be constant. For example, as shown, the first metal pad 201 may include a rectangular shape in which the length L4 of the lower face 201BS is equal to the length of the upper face 201US.

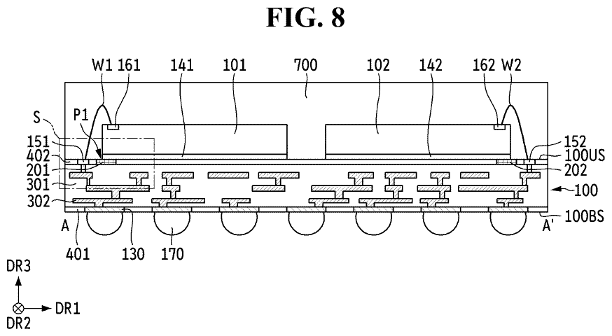

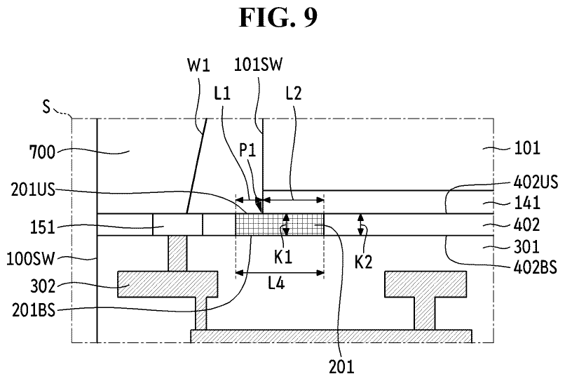

FIG. 8 is a cross-sectional view taken along A-A′ of FIG. 1 to explain a semiconductor package according to some other example embodiments. FIG. 9 is an enlarged view of a region S of FIG. 8 to explain the semiconductor package according to some other example embodiments. For convenience of explanation, in FIGS. 8 and 9, differences from those explained in FIGS. 1 to 3 will be mainly explained, and duplicate descriptions will not be repeated. For convenience of explanation, only the first metal pad 201 will be explained.

Referring to FIGS. 8 and 9, in the semiconductor package according to some other embodiments of the present disclosure, the length of the upper face 201US of the first metal pad 201 may be a combined length of the first length L1 and the second length L2. The length of the upper face 201US of the first metal pad 201 may be equal to the length L4 of the lower face 201BS of the first metal pad 201. In other words, the width of the first metal pad 201 in the first direction DR1 may be constant. For example, as shown, the first metal pad 201 may include a rectangular shape in which the length L4 of the lower face 201BS is equal to the length of the upper face 201US.

The lower face 201BS of the first metal pad 201 may be disposed on the same plane as a lower face 402BS of a second passivation film 402. The upper face 201US of the first metal pad 201 is disposed on the same plane as an upper face 402US of the second passivation film 402. In other words, a thickness K1 of the first metal pad 201 in the third direction DR3 may be the same as a thickness K2 of the second passivation film 402 in the third direction DR3. The first metal pad 201 may not penetrate the inside of the insulating layer 301. The first metal pad 201 may contact an upper surface of the insulating layer 301.

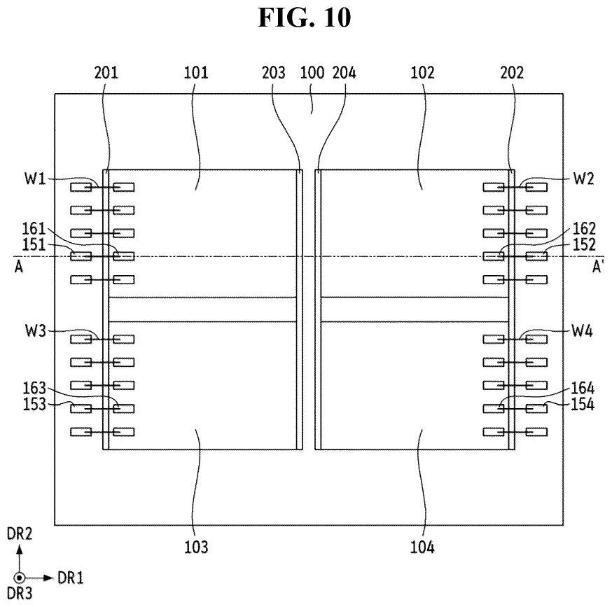

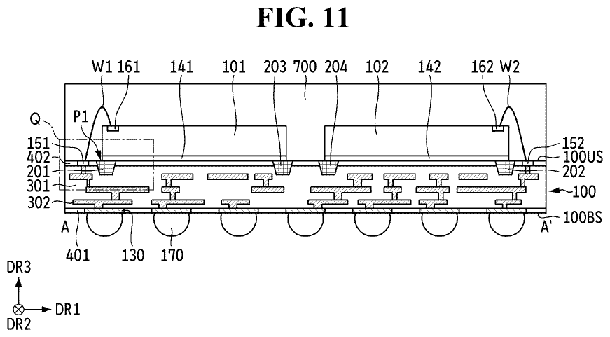

FIG. 10 is an example layout diagram for explaining a semiconductor package according to some other example embodiments. FIG. 11 is a cross-sectional view taken along A-A′ of FIG. 10 to explain the semiconductor package according to some other example embodiments. For convenience of description, in FIGS. 10 and 11, differences from those explained in FIGS. 1 to 3 will be mainly described, and duplicate descriptions will not be repeated. For reference, FIG. 10 is a cross-sectional view in which the encapsulant 700 is omitted for convenience of description. For reference, a region Q shown in FIG. 11 may correspond to the region Q shown in FIG. 3.

Referring to FIGS. 10 and 11, the semiconductor package according to some other embodiments of the present disclosure may further include a third metal pad 203 and a fourth metal pad 204. The third metal pad 203 and the fourth metal pad 204 may be disposed on the upper face of the package substrate 100. The third metal pad 203 may be disposed to abut against the first semiconductor chip 101 and the third semiconductor chip 103. For example, the third metal pad 203 may vertically overlap the first semiconductor chip 101 and the third semiconductor chip 103, and may contact a lower surface of the first adhesive layer 141 and a lower surface of an adhesive layer below the third semiconductor chip 103. The fourth metal pad 204 may be disposed to abut against the second semiconductor chip 102 and the fourth semiconductor chip 104. For example, the fourth metal pad 204 may vertically overlap the second semiconductor chip 102 and the fourth semiconductor chip 104, and may contact a lower surface of the second adhesive layer 142 and a lower surface of an adhesive layer below the fourth semiconductor chip 104. The third metal pad 203 may also be disposed in the space between the first semiconductor chip 101 and the third semiconductor chip 103. For example, the third metal pad 203 may extend continuously from a region below the first semiconductor chip 101 to a region below the third semiconductor chip 103. The fourth metal pad 204 may also be disposed in the space between the second semiconductor chip 102 and the fourth semiconductor chip 104. For example, the fourth metal pad 204 may extend continuously from a region below the second semiconductor chip 102 to a region below the fourth semiconductor chip 104.

The first metal pad 201 and the third metal pad 203 may be disposed with the first semiconductor chip 101 interposed between them. The first metal pad 201 and the third metal pad 203 may be disposed with the third semiconductor chip 103 interposed between them. The second metal pad 202 and the fourth metal pad 204 may be disposed to face each other with the second semiconductor chip 102 interposed between them. The second metal pad 202 and the fourth metal pad 204 may be disposed to face each other with the fourth semiconductor chip 104 interposed between them.

The third metal pad 203 and the fourth metal pad 204 may be formed of or include a metal material. For example, the third metal pad 203 and the fourth metal pad 204 may be formed of or include copper (Cu), but embodiments are not limited thereto. The third metal pad 203 and the fourth metal pad 204 may not come into contact with the metal wiring layer 302 in the package substrate 100. In other words, an electrical signal may not be transmitted through the third metal pad 203 and the fourth metal pad 204. In example embodiments, the third metal pad 203 and the fourth metal pad 204 may be electrically isolated.

The third metal pad 203 may come into direct contact with the side wall 101SW of the first semiconductor chip 101. The third metal pad 203 may penetrate the second passivation film 402. The third metal pad 203 may penetrate the second passivation film 402 and come into contact with the insulating layer 301 in the package substrate 100. The third metal pad 203 may have the same structure and shape as the first metal pad 204, discussed above in connection with any of the embodiments of FIGS. 1-9.

The fourth metal pad 204 may come into direct contact with the side wall of the second semiconductor chip 102. The fourth metal pad 204 may penetrate the second passivation film 402. The fourth metal pad 204 may penetrate the second passivation film 402 and come into contact with the insulating layer 301 in the package substrate 100. The fourth metal pad 204 may have the same structure and shape as the first metal pad 204, discussed above in connection with any of the embodiments of FIGS. 1-9.

The first metal pad 201 and the third metal pad 203 may prevent the package substrate 100 from being deformed, even with the pressure applied by disposing the first semiconductor chip 101 on the package substrate 100. The first metal pad 201 and the third metal pad 203 may prevent the package substrate 100 from being deformed, even with the pressure applied by disposing the third semiconductor chip 103 on the package substrate 100.

The second metal pad 202 and the fourth metal pad 204 may prevent the package substrate 100 from being deformed, even with the pressure applied by disposing the second semiconductor chip 102 on the package substrate 100. The second metal pad 202 and the fourth metal pad 204 may prevent the package substrate 100 from being deformed, even with the pressure applied by disposing the fourth semiconductor chip 104 on the package substrate 100.

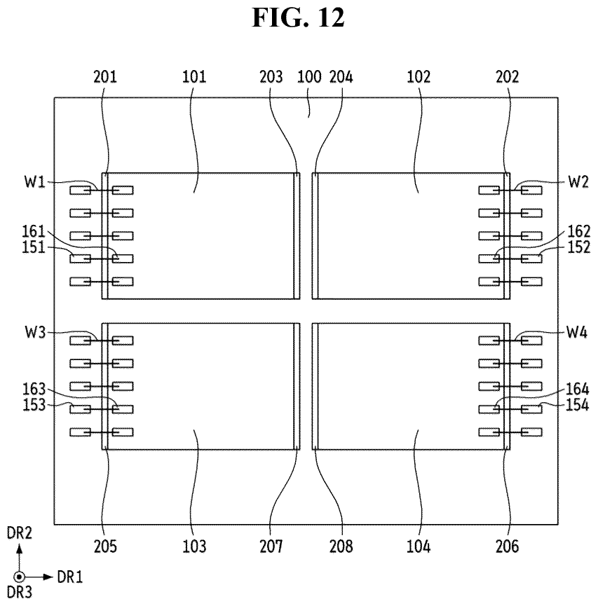

FIG. 12 is an example layout diagram for explaining a semiconductor package according to some other example embodiments. For convenience of explanation, FIG. 12 will mainly explain the differences from those explained in FIGS. 1 to 3, and duplicate descriptions will not be repeated. For reference, FIG. 12 is a cross-sectional view in which the encapsulant 700 is omitted for convenience of explanation.

Referring to FIG. 12, a semiconductor package according to some other embodiments of the present disclosure may further include third to eighth metal pads 203, 204, 205, 206, 207, and 208. For reference, a region Q shown in FIG. 11 may correspond to the region Q shown in FIG. 3.

The first to eighth metal pads 201, 202, 203, 204, 205, 206, 207, and 208 may be disposed on the upper face of the package substrate 100. A first metal pad 201 and a third metal pad 203 may be disposed with the first semiconductor chip 101 interposed between them. A second metal pad 202 and a fourth metal pad 204 may be disposed with the second semiconductor chip 102 interposed between them. A fifth metal pad 205 and a seventh metal pad 207 may be disposed with the third semiconductor chip 103 interposed between them. A sixth metal pad 206 and an eighth metal pad 208 may be disposed with the fourth semiconductor chip 104 interposed between them.

The first metal pad 201 and the third metal pad 203 may be disposed to come into contact with the side walls of the first semiconductor chip 101. The second metal pad 202 and the fourth metal pad 204 may be disposed to come into contact with the side walls of the second semiconductor chip 102. The fifth metal pad 205 and the seventh metal pad 207 may be disposed to come into contact with the side walls of the third semiconductor chip 103. The sixth metal pad 206 and the eighth metal pad 208 may be disposed to come into contact with the side walls of the fourth semiconductor chip 104.

The first to eighth metal pads 201, 202, 203, 204, 205, 206, 207, and 208 may be formed of or include a metal material. The first to eighth metal pads 201, 202, 203, 204, 205, 206, 207, and 208 may be formed of or include, for example, copper (Cu), but embodiments are not limited thereto. The first to eighth metal pads 201, 202, 203, 204, 205, 206, 207, and 208 may not come into contact with the metal wiring layer 302 in the package substrate 100. In other words, electrical signals may not be transmitted through the first to eighth metal pads 201, 202, 203, 204, 205, 206, 207, and 208. For example, the first to eighth metal pads 201, 202, 203, 204, 205, 206, 207, and 208 may be electrically isolated.

The first metal pad 201 and the third metal pad 203 may prevent the package substrate 100 from being deformed, even with the pressure applied by disposing the first semiconductor chip 101 on the package substrate 100. The second metal pad 202 and the fourth metal pad 204 may prevent the package substrate 100 from being deformed, even with the pressure applied by disposing the second semiconductor chip 102 on the package substrate 100. The fifth metal pad 205 and the seventh metal pad 207 may prevent the package substrate 100 from being deformed, even with the pressure applied by disposing the third semiconductor chip 103 on the package substrate 100. The sixth metal pad 206 and the eighth metal pad 208 may prevent the package substrate 100 from being deformed, even with the pressure applied by disposing the fourth semiconductor chip 104 on the package substrate 100.

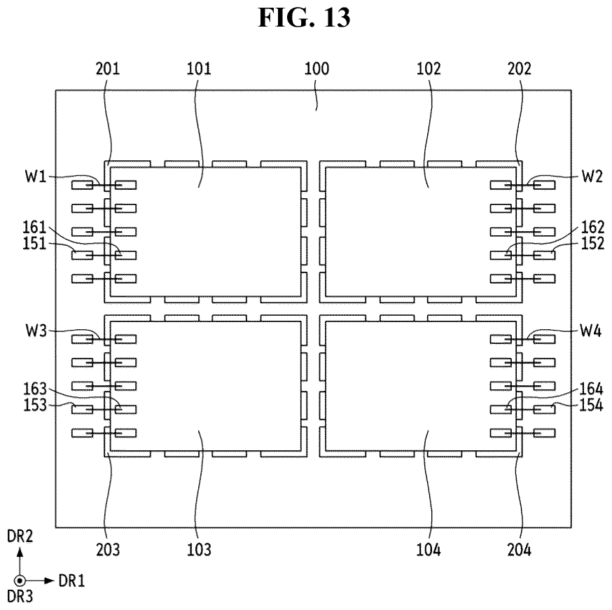

FIG. 13 is an example layout diagram for explaining a semiconductor package according to some other example embodiments. For reference, FIG. 13 is a cross-sectional view in which the encapsulant 700 is omitted for convenience of explanation. For convenience of explanation, FIG. 13 will mainly explain differences from those explained in FIGS. 1 to 3, and duplicate descriptions will not be repeated.

Referring to FIG. 13, the first metal pad 201 may be disposed on the upper face of the package substrate 100. The first metal pad 201 may be disposed along at least a part of the edge of the first semiconductor chip 101. For example, the first metal pad 201 may be disposed to come into contact with a part of the side wall of the first semiconductor chip 101 and not to come into contact with a remaining part.

The first metal pad 201 may be disposed to come into contact with a bent portion of the edge of the first semiconductor chip 101, i.e., a corner. Because the first metal pad 201 is disposed to come into contact with the corner of the first semiconductor chip 101, the first metal pad 201 may prevent the package substrate 100 from being deformed, even with the pressure applied by disposing the first semiconductor chip 101 on the package substrate 100.

Although only the first metal pad 201 has been described, this is only for convenience of description, and the second to fourth metal pads 202, 203, and 204 may be disposed in the same manner as the first metal pad 201.

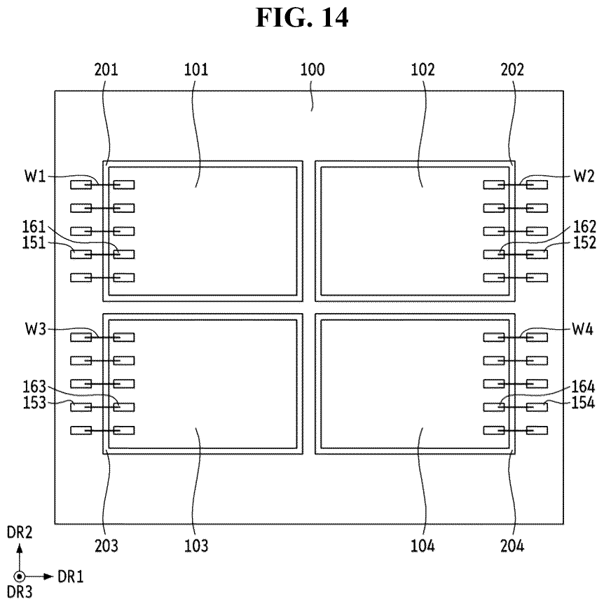

FIG. 14 is an example layout diagram for explaining a semiconductor package according to some other example embodiments. For reference, FIG. 14 is a cross-sectional view in which the encapsulant 700 is omitted for convenience of description. For convenience of description, FIG. 14 will mainly explain differences from those explained in FIGS. 1 to 3, and duplicate descriptions will not be repeated.

Referring to FIG. 14, the first metal pad 201 may be disposed on the upper face of the package substrate 100. The first metal pad 201 may be disposed along the edge of the first semiconductor chip 101. For example, the first metal pad 201 may come into contact with all of the side walls of the first semiconductor chip 101.

Because the first metal pad 201 may be disposed to come into contact with the edge of the first semiconductor chip 101, the first metal pad 201 may prevent the package substrate 100 from being deformed, even with the pressure applied by disposing the first semiconductor chip 101 on the package substrate 100.

Although only the first metal pad 201 has been described, this is only for convenience of description, and each of the second to fourth metal pads 202, 203, and 204 may also be disposed on the second to fourth semiconductor chips 102, 103, and 104 in the same manner as the first metal pad 201.

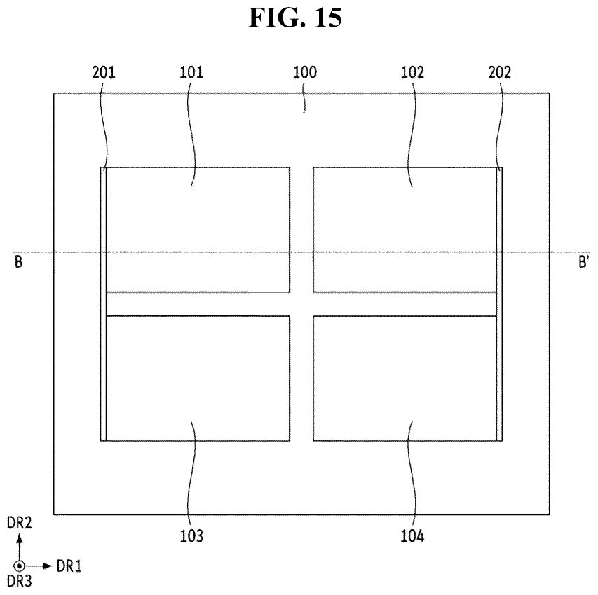

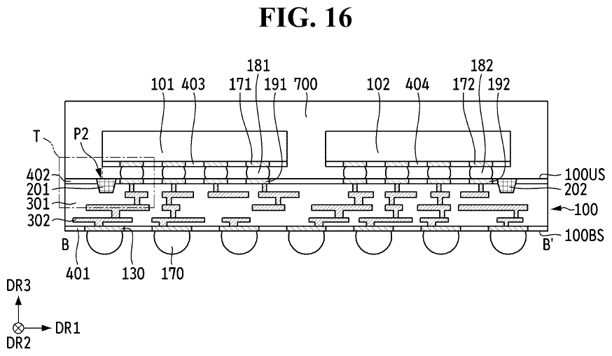

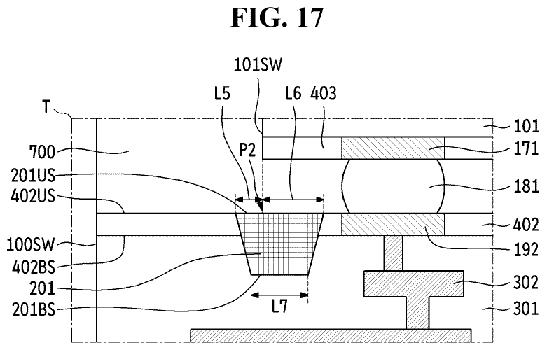

FIG. 15 is an example layout diagram for explaining a semiconductor package according to some other example embodiments. FIG. 16 is a cross-sectional view taken along B-B′ of FIG. 15 to explain the semiconductor package according to another example embodiment. FIG. 17 is an enlarged view of a region T of FIG. 16 to explain the semiconductor package according to another example embodiment. For reference, FIG. 15 is a cross-sectional view in which the encapsulant 700 is omitted for convenience of explanation. For convenience of explanation, FIG. 15 will mainly explain differences from those explained in FIGS. 1 to 3, and duplicate description will not be repeated.

Referring to FIGS. 15 to 17, the semiconductor package according to some other embodiments of the present disclosure may include the package substrate 100, the first to fourth semiconductor chips 101, 102, 103, and 104, and the encapsulant 700.

The package substrate 100 may include an insulating layer 301, a metal wiring layer 302, substrate connection terminals 170, first connection members 181, second connection members 182, first lower pads 191, second lower pads 192, first upper pads 171, second upper pads 172, a first metal pad 201, and a second metal pad 202. Although a structure between the first and second semiconductor chips 101 and 102 and the package substrate 100 will be described below for convenience of explanation, the structure between the second and third semiconductor chips 103 and 104 and the package substrate 100 may also be the same.

The second passivation film 402, the first lower pad 191, and the second lower pad 192 may be disposed on the upper face 100US of the package substrate 100. The second passivation film 402 may be, for example, a solder resist.

A third passivation film 403 and the first upper pads 171 are disposed on the lower face of the first semiconductor chip 101. The third passivation film 403 may be, for example, a solder resist. The first upper pads 171 may electrically connect the first semiconductor chip 101 and the package substrate 100. The first connection members 181 may be disposed between the first semiconductor chip 101 and the package substrate 100. In other words, the first semiconductor chip 101 and the package substrate 100 may be connected by the first connection members 181. The first upper pads 171 disposed on the lower face of the first semiconductor chip 101 and the first lower pads 191 disposed on the upper face 100US of the package substrate 100 may be electrically connected by the first connection members 181. For example, each of the first connection members 181 may contact one of the first upper pads 171 and one of the first lower pads 191. The first upper pads 171, the first connection members 181, and the first lower pads 191 may include a conductive material. For example, the first upper pad 171, the first connection member 181 and the first lower pad 191 may include gold (Au), silver (Ag), copper (Cu), nickel (Ni) or aluminum (Al).

A fourth passivation film 404 and second upper pads 172 may be disposed on the lower face of the second semiconductor chip 102. The fourth passivation film 404 may be, for example, a solder resist. The second upper pads 172 may electrically connect the second semiconductor chip 102 and the package substrate 100. Second connection members 182 may be disposed between the second semiconductor chip 102 and the package substrate 100. In other words, the second semiconductor chip 102 and the package substrate 100 may be connected by the second connection members 182. The second upper pads 172 disposed on the lower face of the second semiconductor chip 102 and the second lower pads 192 disposed on the upper face 100US of the package substrate 100 may be electrically connected by the second connection members 182. For example, each of the second connection members 182 may contact one of the second upper pads 172 and one of the second lower pads 192. The second upper pads 172, the second connection members 182, and the second lower pads 192 may include a conductive material. For example, the second upper pad 172, the second connection member 182, and the second lower pad 192 may include gold (Au), silver (Ag), copper (Cu), nickel (Ni), or aluminum (Al).

For convenience of explanation, only the structures of the first metal pad 201, the first semiconductor chip 101, and the package substrate 100 will be described below.

When the side wall 101SW of the first semiconductor chip 101 extends along a virtual line, the point P2 at which the line abuts against the upper face 100US of the package substrate 100 may be covered by the first metal pad 201. In other words, the first metal pad 201 abuts against the point P2 at which the line abuts against the upper face 100US of the package substrate 100.

The first metal pad 201 may have a fifth length L5 in a direction toward the side wall 100SW of the package substrate 100, on the basis of the point P2 at which the line abuts against the upper face 100US of the package substrate 100. The first metal pad 201 may have a sixth length L6 in a direction opposite to the direction toward the side wall 100SW of the package substrate 100, on the basis of the point P2 at which the line abuts against the upper face 100US of the package substrate 100. The first semiconductor chip 101 may vertically overlap the upper face 201US of the first metal pad 201 by the sixth length L6. The fifth length L5 may be shorter than the sixth length L6.

The length of the upper face 201US of the first metal pad 201 may be a combined length of the fifth length L5 and the sixth length L6. The length of the upper face 201US of the first metal pad 201 may be longer than the length L7 of the lower face 201BS of the first metal pad 201. In other words, the width of the first metal pad 201 in the first direction DR1 may decrease from the upper face 201US to the lower face 201BS of the first metal pad 201. For example, as shown, the first metal pad 201 may have a trapezoidal shape in which the length L7 of the lower face 201BS is shorter than the length of the upper face 201US.

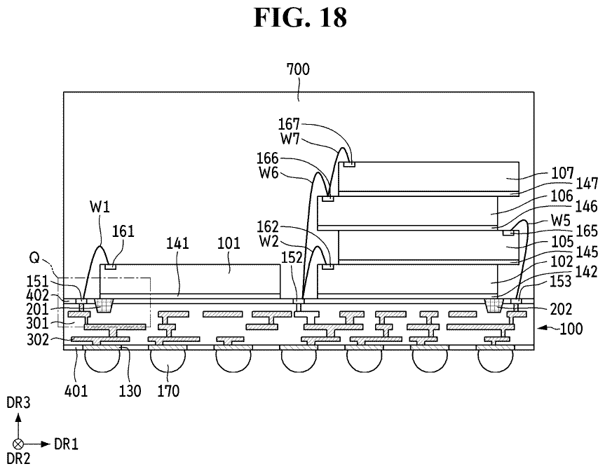

FIG. 18 is a cross-sectional view for explaining the semiconductor packages according to some other example embodiments. For convenience of explanation, FIG. 18 will mainly explain differences from those explained in FIGS. 1 to 3, and duplicate descriptions will not be repeated.

Referring to FIG. 18, a plurality of semiconductor chips 105, 106, and 107 may be stacked on the second semiconductor chip 102. The fifth semiconductor chip 105, the sixth semiconductor chip 106, and the seventh semiconductor chip 107 may be stacked sequentially on the second semiconductor chip 102. For example, the second semiconductor chip 102 and the fifth to seventh semiconductor chips 105, 106, and 107 may be stacked on the package substrate 100 in a stepped cascade type. The second semiconductor chip 102, the fifth semiconductor chip 105, the sixth semiconductor chip 106, and the seventh semiconductor chip 107 may be stacked sequentially in a stepped shape ascending in the third direction DR3. The second semiconductor chip 102, the fifth semiconductor chip 105, the sixth semiconductor chip 106, and the seventh semiconductor chip 107 may be stacked in zigzags.

For reference, FIG. 18 shows a case in which four semiconductor chips 102, 105, 106, and 107 are stacked sequentially, but the embodiment of the present disclosure is not limited thereto. As another example, a semiconductor package according to some other embodiments of the present disclosure may have two or more semiconductor chips stacked sequentially.

The fifth semiconductor chip 105 and the sixth semiconductor chip 106 may include a fifth adhesive layer 145 and a sixth adhesive layer 146, respectively. The fifth adhesive layer 145 and the sixth adhesive layer 146 may be disposed on the lower faces of the fifth semiconductor chip 105 and the sixth semiconductor chip 106, respectively. The fifth adhesive layer 145 and the sixth adhesive layer 146 may cover the lower faces of the fifth semiconductor chip 105 and the sixth semiconductor chip 106, respectively. The fifth adhesive layer 145 may be disposed between the fifth semiconductor chip 105 and the package substrate 100, and the sixth adhesive layer 146 may be disposed between the sixth semiconductor chip 106 and the package substrate 100. Each of the fifth adhesive layer 145 and the sixth adhesive layer 146 may be formed of or include a non-conductive film (NCF), a non-conductive paste (NCP), an insulating polymer or an epoxy resin. However, the technical idea of the present disclosure is not limited thereto.

A third substrate pad 153 may be disposed on the upper face of the package substrate 100. The third substrate pad 153 may electrically connect the package substrate 100 and the fifth semiconductor chip 105.

A fifth chip pad 165 may be disposed on the upper face of the fifth semiconductor chip 105. A sixth chip pad 166 may be disposed on the upper face of the sixth semiconductor chip 106. A seventh chip pad 167 may be disposed on the upper face of the seventh semiconductor chip 107.

The fifth chip pad 165 may be used to electrically connect the fifth semiconductor chip 105 to other components. The sixth chip pad 166 may be used to electrically connect the sixth semiconductor chip 106 to other components. The seventh chip pad 167 may be used to electrically connect the seventh semiconductor chip 107 to other components. The fifth to seventh chip pads 165, 166, and 167 may include a conductive material. For example, the fifth to seventh chip pads 165, 166, and 167 may include gold (Au), silver (Ag), copper (Cu), nickel (Ni), or aluminum (Al).

The fifth semiconductor chip 105 may be electrically connected to the package substrate 100 through the fifth wire W5. For example, the fifth semiconductor chip 105 may be electrically connected to the package substrate 100 by the fifth chip pad 165, the fifth wire W5, and the third substrate pad 153.

The sixth semiconductor chip 106 may be electrically connected to the package substrate 100 through a sixth wire W6. For example, the sixth semiconductor chip 106 may be electrically connected to the package substrate 100 through the sixth chip pad 166, the sixth wire W6, and the second substrate pad 152.

The seventh semiconductor chip 107 may be electrically connected to the sixth semiconductor chip 106 through a seventh wire W7. For example, the seventh semiconductor chip 107 may be electrically connected to the sixth semiconductor chip 106 by the sixth chip pad 166, the seventh wire W7, and the seventh chip pad 167.

For example, the fifth to seventh semiconductor chips 105, 106, and 107 may be logic semiconductor chips. The logic semiconductor chips may be, for example, but not limited to, application processors (AP) such as a central processing unit (CPU), a graphic processing unit (GPU), a field-programmable gate array (FPGA), a digital signal processor, an encryption processor, a micro processor, a micro controller, and an application-specific IC (ASIC).

As another example, the fifth to seventh semiconductor chips 105, 106, and 107 may be memory semiconductor chips. The memory semiconductor chip may be, for example, volatile memories such as a dynamic random access memory (DRAM) or a static random access memory (SRAM). Alternatively, the memory semiconductor chips included in the fifth to seventh semiconductor chips 105, 106, and 107 may be non-volatile memories such as a flash memory, a phase-change random access memory (PRAM), a magnetic random access memory (MRAM), a ferroelectronic random access memory (FeRAM) or a resistive random access memory (RRAM).

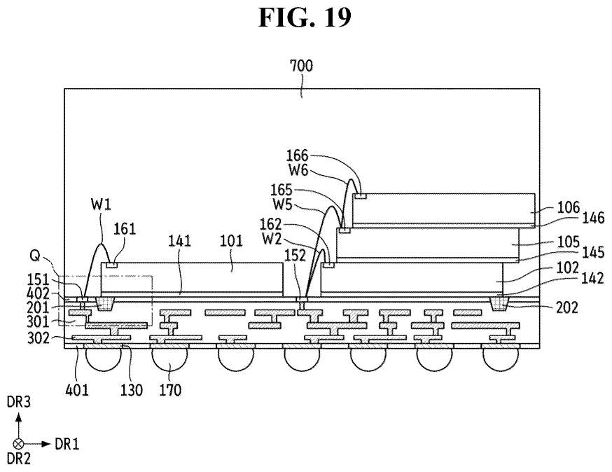

FIG. 19 is a cross-sectional view for explaining a semiconductor package according to some other example embodiments. For convenience of explanation, FIG. 19 will mainly explain differences from those explained in FIG. 18, and duplicate descriptions will not be repeated.

Referring to FIG. 19, a plurality of semiconductor chips 105 and 106 may be stacked on the second semiconductor chip 102. The fifth semiconductor chip 105 and the sixth semiconductor chip 106 may be stacked sequentially on the second semiconductor chip 102. For example, the second semiconductor chip 102 and the fifth and sixth semiconductor chips 105 and 106 may be stacked on the package substrate 100 in a stepped cascade type.

For reference, FIG. 19 shows a case in which the three semiconductor chips 102, 105, and 106 are stacked sequentially, but the embodiment of the present disclosure is not limited thereto. As another example, in a semiconductor package according to some other embodiments of the present disclosure, two or more semiconductor chips may be stacked sequentially.

The second semiconductor chip 102, the fifth semiconductor chip 105, and the sixth semiconductor chip 106 may be stacked sequentially in a stepped shape ascending in the third direction DR3. For example, the second semiconductor chip 102, the fifth semiconductor chip 105, and the sixth semiconductor chip 106 may include a stepped shape ascending in one direction.

The fifth semiconductor chip 105 may be electrically connected to the package substrate 100 through the fifth wire W5. For example, the fifth semiconductor chip 105 may be electrically connected to the package substrate 100 by the fifth chip pad 165, the fifth wire W5, and the second substrate pad 152.

The sixth semiconductor chip 106 may be electrically connected to the fifth semiconductor chip 105 through the sixth wire W6. For example, the sixth semiconductor chip 106 may be electrically connected to the fifth semiconductor chip 105 by the sixth chip pad 166, the sixth wire W6, and the fifth chip pad 165.

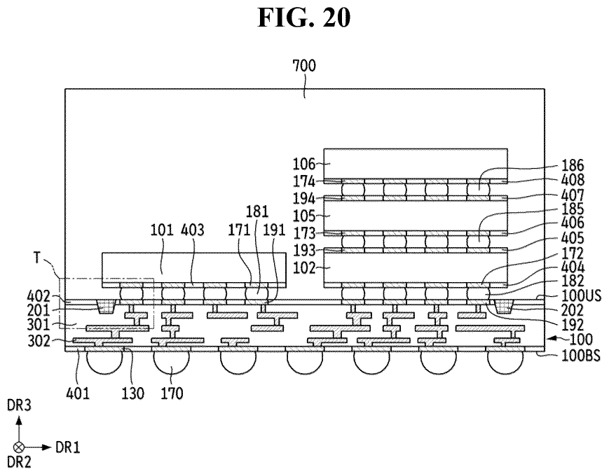

FIG. 20 is a cross-sectional view for explaining a semiconductor package according to some other example embodiments. For convenience of explanation, FIG. 20 will mainly explain differences from those explained in FIGS. 15 to 17, and duplicate descriptions will not be repeated. For reference, a region T shown in FIG. 20 may correspond to a region T shown in FIG. 16.

Referring to FIG. 20, a plurality of semiconductor chips 105 and 106 may be stacked on the second semiconductor chip 102. A fifth semiconductor chip 105 and a sixth semiconductor chip 106 may be stacked sequentially on the second semiconductor chip 102. For example, the second semiconductor chip 102, the fifth semiconductor chip 105, and the sixth semiconductor chip 106 may be stacked sequentially in the third direction DR3.

For reference, FIG. 20 shows a case in which three semiconductor chips 102, 105, and 106 are stacked sequentially, but the embodiment of the present disclosure is not limited thereto. As another example, in a semiconductor package according to another embodiment of the present disclosure, two or more semiconductor chips may be stacked sequentially.

A fifth passivation film 405 and third lower pads 193 may be disposed on the upper face of the second semiconductor chip 102. The fifth passivation film 405 may be, for example, a solder resist. The third lower pads 193 may electrically connect the second semiconductor chip 102 and the fifth semiconductor chip 105.

A sixth passivation film 406 and third upper pads 173 may be disposed on the lower face of the fifth semiconductor chip 105. The sixth passivation film 406 may be, for example, a solder resist. The third upper pads 173 may electrically connect the second semiconductor chip 102 and the fifth semiconductor chip 105.

Fifth connection members 185 may be disposed between the third lower pads 193 and the third upper pads 173. The second semiconductor chip 102 and the fifth semiconductor chip 105 may be connected by the fifth connection members 185. The third lower pads 193 disposed on the upper face of the second semiconductor chip 102 and the third upper pads 173 disposed on the lower face of the fifth semiconductor chip 105 may be electrically connected by the fifth connection members 185. The third lower pads 193, the fifth connection members 185, and the third upper pads 173 may include a conductive material. For example, the third lower pads 193, the fifth connection members 185, and the third upper pads 173 may include gold (Au), silver (Ag), copper (Cu), nickel (Ni), or aluminum (Al).

A seventh passivation film 407 and fourth lower pads 194 may be disposed on the upper face of the fifth semiconductor chip 105. The seventh passivation film 407 may be, for example, a solder resist. The fourth lower pads 194 may electrically connect the fifth semiconductor chip 105 and the seventh semiconductor chip 107.

An eighth passivation film 408 and fourth upper pads 174 may be disposed on the lower face of the seventh semiconductor chip 107. The eighth passivation film 408 may be, for example, a solder resist. The fourth upper pads 174 may electrically connect the fifth semiconductor chip 105 and the seventh semiconductor chip 107.

Sixth connection members 186 may be disposed between the fourth lower pads 194 and the fourth upper pads 174. The fifth semiconductor chip 105 and the seventh semiconductor chip 107 may be connected by a sixth connection members 186. The fourth lower pads 194 disposed on the upper face of the fifth semiconductor chip 105 and the fourth upper pads 174 disposed on the lower face of the seventh semiconductor chip 107 may be electrically connected by the sixth connection members 186. The fourth lower pads 194, the sixth connection members 186, and the fourth upper pads 174 may include a conductive material. For example, the fourth lower pads 194, the sixth connection members 186, and the fourth upper pads 174 may include gold (Au), silver (Ag), copper (Cu), nickel (Ni) or aluminum (Al).

In concluding the detailed description, those skilled in the art will appreciate that many variations and modifications may be made to the disclosed embodiments without substantially departing from the principles of the present inventive concept. Therefore, the disclosed embodiments of the disclosure are used in a generic and descriptive sense only and not for purposes of limitation.

What is claimed is:

1. A semiconductor package comprising:
a substrate;
a semiconductor chip which is disposed on the substrate, and includes a plurality of edges; and
a metal pad which is disposed inside the substrate, and directly abuts against at least one edge of the plurality of edges,
wherein the metal pad is electrically isolated.

2. The semiconductor package of claim 1,
wherein the metal pad protrudes from the one edge of the semiconductor chip away from the semiconductor chip by a first length, and
wherein the metal pad protrudes from the one edge of the semiconductor chip to inside of the semiconductor chip by a second length, the first length being different from the second length.

3. The semiconductor package of claim 2,
wherein the first length is shorter than the second length.

4. The semiconductor package of claim 1,
wherein a width of an upper face of the metal pad in a first direction, which is a horizontal direction of the substrate, is greater than a width of a lower face of the metal pad in the first direction.

5. The semiconductor package of claim 1,
wherein the substrate includes a passivation film that covers an upper face of the substrate, and
wherein a lower face of the metal pad is disposed on the same plane as a lower face of the passivation film.

6. The semiconductor package of claim 1,
wherein a width of an upper face of the metal pad in a first direction, which is the horizontal direction of the substrate, is equal to a width of a lower face of the metal pad in the first direction.

7. The semiconductor package of claim 1,
wherein the substrate further includes a plurality of metal wirings, and
wherein the metal pad does not come into contact with the plurality of metal wirings.

8. The semiconductor package of claim 1,
wherein the metal pad includes copper.

9. The semiconductor package of claim 1,
wherein an upper face of the metal pad is disposed on the same plane as an upper face of the substrate.

10. A semiconductor package comprising:
a first semiconductor chip and a second semiconductor chip which are mounted on a substrate to be spaced apart from each other;
a first metal pad which is disposed in the substrate and comes into contact with an edge of the first semiconductor chip; and
a second metal pad which is disposed in the substrate and comes into contact with an edge of the second semiconductor chip,
wherein each of the first metal pad and the second metal pad is electrically isolated.

11. The semiconductor package of claim 10, further comprising:
a third metal pad which is disposed in the substrate and comes into contact with the edge of the first semiconductor chip; and
a fourth metal pad which is disposed in the substrate and comes into contact with the edge of the second semiconductor chip,
wherein the first semiconductor chip and the second semiconductor chip are disposed side by side in a first direction, and
wherein the first to fourth metal pads are disposed to overlap in the first direction.

12. The semiconductor package of claim 10,
wherein the substrate includes a passivation film which covers an upper face of the substrate,
wherein a lower face of the first metal pad is disposed on the same plane as a lower face of the passivation film, and
wherein a lower face of the second metal pad is disposed on the same plane as the lower face of the passivation film.

13. The semiconductor package of claim 10,
wherein the substrate includes a passivation film that covers an upper face of the substrate,
wherein a lower face of the first metal pad is disposed to be closer to a lower face of the substrate than a lower face of the passivation film, and
wherein a lower face of the second metal pad is disposed to be closer to the lower face of the substrate than the lower face of the passivation film.

14. The semiconductor package of claim 10,
wherein the substrate includes a passivation film that covers an upper face of the substrate,
wherein an upper face of the first metal pad is disposed on the same plane as an upper face of the passivation film.
wherein an upper face of the second metal pad is disposed on the same plane as the upper face of the passivation film.

15. The semiconductor package of claim 10,
wherein a width of the first metal pad in a horizontal direction of the substrate narrows in a direction toward a lower face of the substrate, and
wherein a width of the second metal pad in the horizontal direction of the substrate narrows in the direction toward the lower face of the substrate.

16. The semiconductor package of claim 10,
wherein a width of the first metal pad in a horizontal direction of the substrate is constant, and
wherein a width of the second metal pad in the horizontal direction of the substrate is constant.

17. The semiconductor package of claim 10,
wherein the first metal pad protrudes from the edge of the first semiconductor chip away from the first semiconductor chip by a first length,
wherein the first metal pad protrudes from the edge of the first semiconductor chip to inside of the first semiconductor chip by a second length, the first length being shorter than the second length,
wherein the second metal pad protrudes from the edge of the second semiconductor chip away from the second semiconductor chip by a third length, and
wherein the second metal pad protrudes from the edge of the second semiconductor chip to inside of the second semiconductor chip by a fourth length, the third length being shorter than the fourth length.

18. A semiconductor package comprising:
a substrate;
a plurality of substrate pads which are disposed on an upper face of the substrate;
a first semiconductor chip which is disposed on the substrate and includes a plurality of edges;
a plurality of chip pads which are disposed on an upper face of the first semiconductor chip;
a plurality of wires which connect the plurality of substrate pads and the plurality of chip pads one-to-one;
a metal pad which is disposed in the substrate and directly abuts against at least one edge of the plurality of edges; and
a plurality of second semiconductor chips which are stacked on the first semiconductor chip in a cascade type,
wherein the metal pad is electrically isolated.

19. The semiconductor package of claim 18,
wherein the metal pad protrudes from the at least one edge of the first semiconductor chip away from the first semiconductor chip by a first length,
wherein the metal pad protrudes from the at least one edge of the first semiconductor chip to inside of the first semiconductor chip by a second length, and
wherein the first length is shorter than the second length.

20. The semiconductor package of claim 18,
wherein the substrate includes a passivation film which covers an upper face of the substrate, and
wherein a lower face of the metal pad is disposed on the same plane as a lower face of the passivation film.
